(19) United States
(12) Patent Application Publication
(10) Pub. No.: US 2021/0325787 A1
(43) Pub. Date: Oct. 21, 2021

(54) EXPOSURE APPARATUS AND METHOD OF MANUFACTURING DISPLAY DEVICE USING THE SAME

(71) Applicants: Samsung Display Co., Ltd., Yongin-Si (KR); POSTECH Research and Business Development Foundation, Pohang-si (KR)

(72) Inventors: Sung Soon IM, Suwon-si (KR); Jong Kyu KIM, Pohang-si (KR); Jeong Hyeon PARK, Pohang-si (KR); Seung Yong SONG, Suwon-si (KR); Duck Jung LEE, Hwaseong-si (KR); Jong Won LEE, Hwaseong-si (KR)

(21) Appl. No.: 16/952,953

(22) Filed: Nov. 19, 2020

(30) Foreign Application Priority Data
Apr. 16, 2020 (KR) 10-2020-0045791

(51) Int. Cl. G03F 7/20; H01L 27/15; H01L 27/12; H01L 51/56; H01L 51/00

(52) U.S. Cl. CPC G03F 7/70391; H01L 27/156; H01L 51/0011; H01L 51/56; H01L 27/1288

(57) ABSTRACT

Provided are an exposure apparatus including a light source unit which provides light for exposure and comprises micro light emitting diodes arranged in a matrix form; a substrate transfer unit which transfers a target substrate; and a control unit which controls at least one of the light source unit and the substrate transfer unit. The control unit allocates coordinates or an address to each micro light emitting diode and individually controls an amount of light of each micro light emitting diode according to a preset pattern based on the coordinates or the address.

This application claims the benefit of Korean Patent Application No. 10-2020-0045791, filed on Apr. 16, 2020, in the Korean Intellectual Property Office, the disclosure of which is incorporated herein by reference in its entirety.

### BACKGROUND

### 1. Field

The present disclosure relates to an exposure apparatus and a method of manufacturing a display device using the same.

### 2. Description of the Related Art

A photolithography device is a device that forms complicated circuit patterns using light, like photo printing technology. The photolithography device may be used in pattern forming for manufacturing, for example, semiconductor devices, display panels such as liquid crystal displays (LCDs), plasma display panels (PDPs) and electroluminescent displays (ELDs), integrated circuits, and flat panel displays.

In conventional photolithography, a desired pattern is formed on a substrate coated with a photoresist by exposing the photoresist to light through a photomask in which a pattern is formed of a metal thin film, e.g., mainly chromium, on a quartz or glass plate.

In the above process, a patterning device composed of an array of individually operable elements may be used instead of the photomask. The patterning device is programmed to form a beam of a desired pattern using the array of the individually operable elements. This “maskless” system can form patterns of various shapes at no additional cost because a beam radiated through the program can be modified into a desired pattern. In addition, the maskless system is faster and cheaper than a conventional mask-based system.

A representative programmable patterning device is an exposure apparatus using a digital minor device (DMD). The DMD is a device used as an element for generating images in electronic products such as projectors and televisions and is a key component for generating patterns in a maskless lithography system. In the DMD, a minor rotates according to an electrical signal to form an image of a desired pattern. That is, the DMD is like a photomask capable of pattern modification. An exposure apparatus using the DMD allows easy use of previous data when its design is changed, can be immediately corrected for design errors, and can reduce design time. On the other hand, the DMD requires a complicated optical system for patterning image projection and suffers from light loss because light is irradiated through the DMD.

### SUMMARY

Aspects of the present disclosure provide an exposure apparatus which can form various patterns without replacement of a light source or a mask and a method of manufacturing a display device using the exposure apparatus.

Aspects of the present disclosure also provide an exposure apparatus with low light loss and a method of manufacturing a display device using the exposure apparatus.

Aspects of the present disclosure also provide an exposure apparatus which can save an installation space and a method of manufacturing a display device using the exposure apparatus.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to an aspect of the present disclosure, there is provided an exposure apparatus including a light source unit which provides light for exposure and comprises micro light emitting diodes arranged in a matrix form; a substrate transfer unit which transfers a target substrate; and a control unit which controls at least one of the light source unit and the substrate transfer unit. The control unit allocates coordinates or an address to each micro light emitting diode and individually controls an amount of light of each micro light emitting diode according to a preset pattern based on the coordinates or the address.

According to another aspect of the present disclosure, there is provided an exposure apparatus including a light source unit which provides light for exposure and comprises unit light emitting cells arranged in a matrix form; a substrate transfer unit which transfers a target substrate; and a control unit which controls at least one of the light source unit and the substrate transfer unit. The control unit allocates coordinates or an address to each unit light emitting cell and individually controls an amount of light of each unit light emitting cell according to a preset pattern based on the coordinates or the address.

According to another aspect of the present disclosure, there is provided a method of manufacturing a display device including stacking at least one material layer on a base substrate; coating a photosensitive material on the at least one material layer; outputting a preset pattern by individually controlling an amount of light of each micro light emitting diode; exposing the photosensitive material to light; removing a part of the photosensitive material; and etching a first pattern in the at least one material layer.

### BRIEF DESCRIPTION OF THE DRAWINGS

These and/or other aspects will become apparent and more readily appreciated from the following description of the embodiments, taken in conjunction with the accompanying drawings.

FIG. 1 is a perspective view of an exposure apparatus according to an embodiment.

FIG. 2 is a plan view of the exposure apparatus of FIG. 1 as viewed from above.

FIG. 3 is a plan view of a light source unit of FIG. 1 as viewed from below.

FIG. 4 is a cross-sectional view taken along line A-A′ of FIG. 3.

FIG. 5 illustrates an auxiliary optical system.

FIGS. 6, 7, 8, 9, 10, and 11 illustrate a method of controlling an exposure apparatus according to an embodiment of the present disclosure.

FIGS. 12, 13, and 14 illustrate a method of controlling an exposure apparatus according to an embodiment of the present disclosure.

FIGS. 15, 16, 17, 18, 19, and 20 illustrate a method of manufacturing a display device according to an embodiment of the present disclosure.

FIGS. 21, 22, 23, and 24 illustrate an exposure apparatus and a method of manufacturing a display device using the same according to an embodiment of the present disclosure.

### DETAILED DESCRIPTION

The inventive concept will now be described more fully hereinafter with reference to the accompanying drawings, in which embodiments are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Although the terms “first”, “second”, etc. may be used herein to describe various elements, these elements should not be limited by these terms. These terms may be used to distinguish one element from another element. Thus, a first element discussed below may be termed a second element without departing from teachings of one or more exemplary embodiments.

Hereinafter, specific embodiments will be described with reference to the attached drawings.

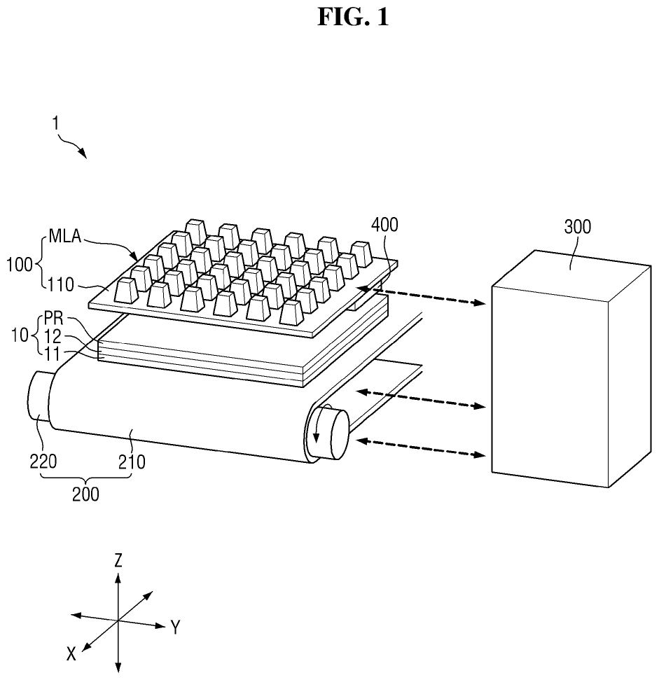

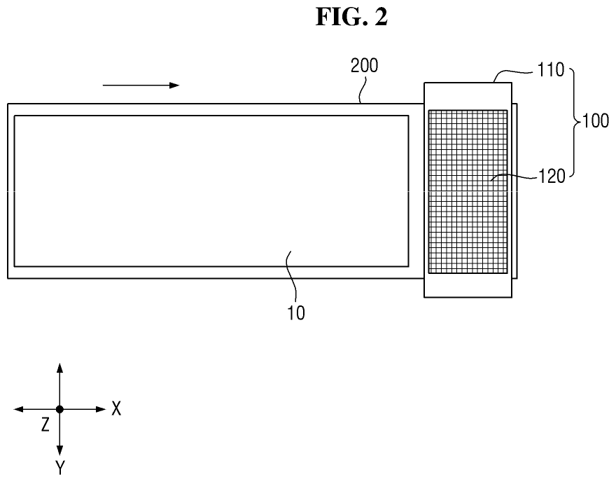

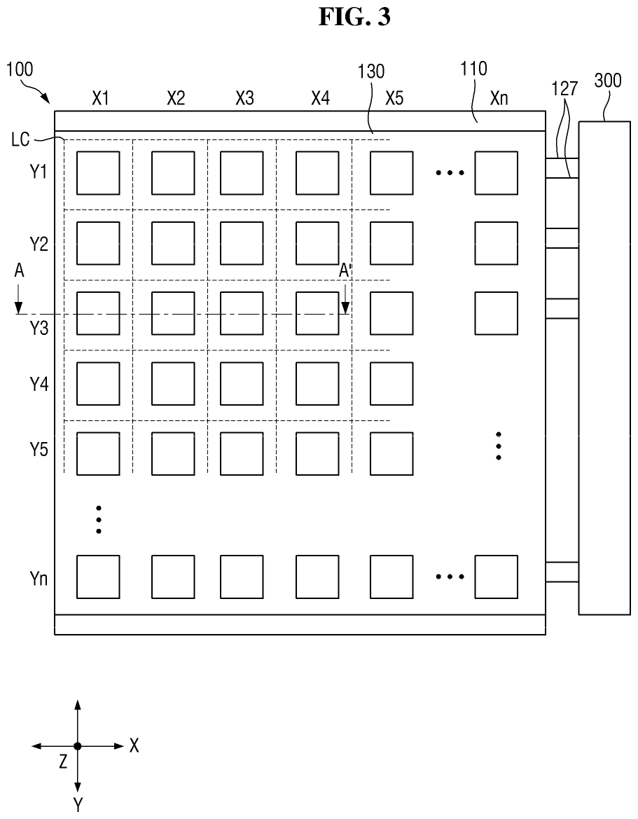

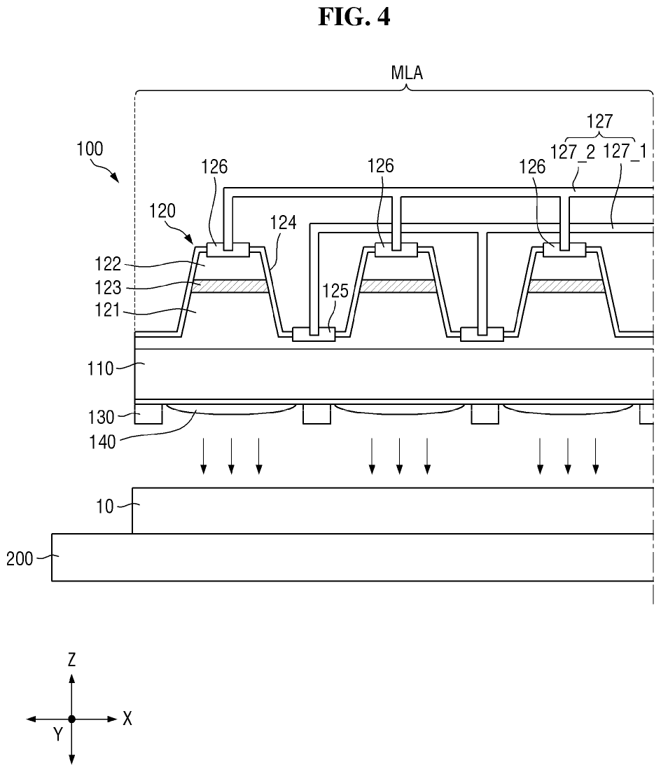

FIG. 1 is a perspective view of an exposure apparatus 1 according to an embodiment. FIG. 2 is a plan view of the exposure apparatus 1 of FIG. 1 as viewed from above. FIG. 3 is a plan view of a light source unit 100 of FIG. 1 as viewed from below. FIG. 4 is a cross-sectional view taken along line A-A′ of FIG. 3.

In embodiments, a first direction X, a second direction Y, and a third direction Z intersect each other in different directions. In the drawings, a horizontal direction of the exposure apparatus 1 is defined as the first direction X, a vertical direction as the second direction Y, and a height direction as the third direction Z. The third direction Z includes an upward direction toward an upper side in the drawings and a downward direction toward a lower side in the drawings. Accordingly, a surface of a member disposed to face the upward direction may be referred to as an upper surface, and the other surface of the member disposed to face the downward direction may be referred to as a lower surface. However, directions mentioned in the embodiments should be understood as relative directions.

The exposure apparatus 1 will be described below as, for example, a maskless photolithography apparatus that does not require an optical mask in a photolithography process generally using photoresist. However, the exposure apparatus 1 may be any apparatus used in an exposure and development process for pattern formation.

Referring to FIGS. 1 through 4, the exposure apparatus 1 includes the light source unit 100, a substrate transfer unit 200, and a control unit 300. The exposure apparatus 1 may further include a sensing unit 400.

The light source unit 100 includes light emitting elements and is disposed above the substrate transfer unit 200. The light source unit 100 may project light downward toward a target substrate 10 loaded on the substrate transfer unit 200.

The light source unit 100 may expose the target substrate 10 to light so that a layer including photosensitive material PR is cured according to a specific pattern. The target substrate 10 refers to a substrate exposed to light by the exposure apparatus 1. In an embodiment, the target substrate 10 may include a base substrate 11, a material layer 12 stacked on the base substrate 11, and a photosensitive material PR stacked on the material layer 12. The photosensitive material PR includes a photoresist. For example, the photosensitive material PR may be a photosensitive film formed by coating the photoresist on the material layer 12. The material layer 12 may be, for example, a material for forming thin-film transistors.

The light source unit 100 may be disposed to overlap the substrate transfer unit 200. Specifically, the substrate transfer unit 200 may be disposed along the first direction X in which the target substrate 10 is transferred. The light source unit 100 may be disposed along the second direction Y intersecting the first direction X. The substrate transfer unit 200 and the light source unit 100 may at least partially overlap each other in the third direction Z. In an embodiment, a width of the light source unit 100 in the second direction Y may be equal to or greater than a width of the substrate transfer unit 200 in the second direction Y. Accordingly, during exposure, the exposure apparatus 1 may form one pattern in a specific area of the target substrate 10 disposed between the light source unit 100 and the substrate transfer unit 200 through one exposure.

The light source unit 100 may be spaced apart from the substrate transfer unit 200 by a predetermined distance. The predetermined distance may vary according to a thickness of the target substrate 10. Specifically, in the exposure apparatus 1, the light source unit 100 may be disposed close to the substrate transfer unit 200 or the target substrate 10 as an optical system 140 to be described later is integrated with the light source unit 100. Accordingly, an apparatus or system for lithography can be miniaturized, and light loss can be minimized. For example, during exposure, the distance between the light source unit 100 and the substrate transfer unit 200 in the third direction Z may be about 500 μm or less. For another example, during exposure, a distance between the light source unit 100 and the target substrate 10 in the third direction Z may be about 500 μm or less. For another example, during exposure, the distance between the light source unit 100 and the target substrate 10 in the third direction Z may be about 5 μm or less. For another example, during exposure, the distance between the light source unit 100 and the target substrate 10 in the third direction Z may be about 1 μm or more.

Accordingly, it is possible to prevent interference due to a difference in flatness between the light source unit 100 and the target substrate 10 and prevent transfer of a material such as photoresist due to contact between them. In addition, when the light source unit 100 and the target substrate 10 are in excessively close contact with each other, a dark portion may be formed on a part of the target substrate 10 by a light blocking member 130 to be described later. For proper dispersion of light, the light source unit 100 and the target substrate 10 may be spaced apart by a predetermined distance to prevent the formation of the dark portion. In some embodiments, the exposure apparatus 1 may be controlled by the control unit 300 to be described later and may further include a light source moving unit which can move the light source unit 100 in at least one of the first, second, and third directions X, Y, and Z for alignment of the light source unit 100.

The light source unit 100 may be disposed parallel to the target substrate 10. In other words, the light source unit 100 may be disposed parallel to a transfer direction of the substrate transfer unit 200 or an upper surface of the substrate transfer unit 200. Accordingly, the light source unit 100 may uniformly irradiate light to the target unit 10. In an embodiment, the target substrate 10 may be transferred in the first direction X, and the light source unit 100 may be disposed along a plane parallel to the first direction X and the second direction Y. In some embodiments, the light source unit 100 may be inclined to the target substrate 10 or a movement direction of the target substrate 10. In some embodiments, light of the light source unit 100 may be controlled individually according to the inclination by the control unit 300 to be described later.

The light source unit 100 may include unit light emitting cells LC. The unit light emitting cells LC may respectively correspond to micro light emitting diodes (LEDs) 120 of a micro LED array MLA to be described later. The light source unit 100 may be electrically connected to the control unit 300 to be described later, and the unit light emitting cells LC may be individually controlled to be turned on or off by the control unit 300. In some embodiments, the light source unit 100 may further include a driver integrated circuit which transmits a driving signal to a micro LED 120 corresponding to each unit light emitting cell LC, and the driver integrated circuit may drive each micro LED 120 individually based on a control signal received from the control unit 300.

The light source unit 100 may include a light source unit substrate 110, the micro LED array MLA, and the optical system 140. The light source unit 100 may further include the light blocking member 130.

The light source unit substrate 110 is disposed parallel to the target substrate 10 on the substrate transfer unit 200 and supports the bottom of the micro LED array MLA. In an embodiment, a thickness of the light source unit substrate 110 may be about 100 to 200 μm. Accordingly, the first light source substrate 110 may maximize space efficiency, increase light transmittance of the light source, and have a minimum thickness for mounting a configuration such as a thin-film transistor to be described later.

The light source unit substrate 110 may be made of a transparent material to allow light emitted from the micro LEDs 120 to reach the target substrate 10 through the light source unit substrate 110. The light source unit substrate 110 may be made of a transparent insulating material such as sapphire, glass or polymer resin. In some embodiments, the light source unit substrate 110 may include layers made of a transparent conductive material, and the layers may include, for example, a circuit such as a thin-film transistor structure for individually controlling each micro LED 120.

The micro LED array MLA is disposed on the light source unit substrate 110. The micro LED array MLA may include the micro LEDs 120. Here, each of the micro LEDs 120 refers to a light emitting element having a very small size. In an embodiment, the size of each micro LED 120 may be 100 μm or less. In some embodiments, the size of each micro LED 120 may be 20 to 40 μm.

The micro LEDs 120 may be arranged in rows and columns along the first direction X and the second direction Y intersecting the first direction X. In an embodiment, the first direction X and the second direction Y may perpendicularly intersect each other. Since each micro LED 120 has a very small size, at least hundreds or thousands of micro LEDs 120 may be arranged along the first direction X and the second direction Y. In an embodiment, the micro LEDs 120 may be arranged such that an average pitch between the micro LEDs 120 is 5000 μm or less. In some embodiments, the average pitch between the micro LEDs 120 may be 20 to 40 μm.

The micro LEDs 120 project light downward toward the substrate transfer unit 200 or the target substrate 10. Each micro LED 120 may emit light having a wavelength in a specific region. Specifically, an emission wavelength of each micro LED 120 may include an ultraviolet region. For example, the emission wavelength of each micro LED 120 may be 200 to 500 nm. Light emitted from each micro LED 120 may pass through the light source unit substrate 110 and the optical system 140 to reach the target substrate 10. Each micro LED 120 may become wider toward the bottom in order for efficient light extraction. For example, each micro LED 120 may have various shapes such as a cone, a triangular pyramid, a quadrangular pyramid, a hexahedron, a quadrangular prism, and a cylinder.

Each micro LED 120 may include a first semiconductor layer 121, a second semiconductor layer 122, an active layer 123, a first electrode 125, a second electrode 126, a reflector 124, and a control unit circuit 127.

The first semiconductor layer 121 may be disposed on the light source unit substrate 110. As illustrated in FIG. 4, the first semiconductor layer 121 of each micro LED 120 may be connected to the first semiconductor layer 121 of a neighboring micro LED 120. The first semiconductor layer 121 may be an n-type semiconductor layer.

The second semiconductor layer 122 is disposed on the active layer 123 to be described later. The second semiconductor layer 122 may be a p-type semiconductor layer.

In FIG. 4, each of the first semiconductor layer 121 and the second semiconductor layer 122 is composed of one layer. However, each of the first semiconductor layer 121 and the second semiconductor layer 122 may also include more than one layer.

The active layer 123 is disposed between the first semiconductor layer 121 and the second semiconductor layer 122. For example, the active layer 123 may have a structure in which a semiconductor material having a large band gap energy and a semiconductor material having a small band gap energy are stacked on each other.

The first electrode 125 electrically connects the first semiconductor layer 121 and a first control unit circuit 127_1 to be described later.

The second electrode 126 electrically connects the second semiconductor layer 122 to a second control unit circuit 127_2 to be described later.

The reflector 124 has an open lower side and surrounds the first semiconductor layer 121, the active layer 123 and the second semiconductor layer 122 from the outside. The reflector 124 reflects light generated by the active layer 123 downward.

The reflector 124 becomes wider toward the bottom so that reflected light is aligned in a certain direction. In an embodiment, side surfaces of the reflector 124 may be inclined at an angle of about 40 to 90 degrees. In some embodiments, the side surfaces of the reflector 124 may be inclined at an angle of about 50 degrees.

The reflector 124 may include a metal having high reflectivity or an alloy of metals. For example, the reflector 124 may include aluminum (Al), gold (Au), silver (Ag), nickel (Ni), copper (Cu), rhodium (Rh), palladium (Pd), zinc (Zn), ruthenium (Ru), lanthanum (La), titanium (Ti), platinum (Pt), or an alloy of the same.

The light blocking member 130 is disposed under the light source unit substrate 110. The light blocking member 130 may be disposed in a lattice shape to form openings corresponding to the micro LEDs 120, respectively. The light blocking member 130 may be disposed along the boundary of a unit light emitting cell LC between the micro LEDs 120. The light blocking member 130 may be made of a material that absorbs or reflects light of at least a specific wavelength band to block transmission of the light. The light blocking member 130 prevents mixing of light emitted from different micro LEDs 120 and reduces reflection of external light. In an embodiment, the light blocking member 130 may be, for example, a black matrix made of a chromium-based metal material, a carbon-based organic material, or a resin.

The control unit circuit 127 electrically connects the light source unit 100 and the control unit 300 and drives each micro LED 120 individually by transmitting a control signal of the control unit 300 to each micro LED 120. The control unit circuit 127 may include an element and/or wiring for individually driving each micro LED 120, for example, may include a data line, a scan line, a transistor, or a driver integrated circuit. In an embodiment, the control unit circuit 127 may include the first control unit circuit 127_1 which electrically connects the first electrodes 125 and the control unit 300 and the second control unit circuit 127_2 which electrically connects the second electrodes 126 and the control unit 300. The first control unit circuit 127_1 and the second control unit circuit 127_2 are disposed parallel to each other in FIG. 4. In some embodiments, the first control unit circuit 127_1 may apply a first power supply voltage to each micro LED 120, and the second control unit circuit 127_2 may apply a second power supply voltage. Here, the second control unit circuit 127_2 includes, for example, a thin-film transistor, and the second power supply voltage is individually applied to each micro LED 120 so that the control unit 300 can drive each micro LED 120 individually.

The optical system 140 is disposed under the light source unit substrate 110. The optical system 140 may guide light emitted from the micro LEDs 120 in a specific direction to uniformly align the overall direction of the light. In some embodiments, the optical system 140 may enlarge or reduce light emitted from the micro LEDs 120.

Since the optical system 140 is integrated under the light source unit substrate 110 to be adjacent to the micro LED array MLA, the light source unit 100 may be disposed in the simple shape of bars having rectangular shape overlapping the substrate transfer unit 200 in a plane view as illustrated in FIG. 3. That is, the exposure apparatus 1 may use light emitting elements having a fine size and integrated with the optical system 140. Thus, an apparatus or system for photolithography can be miniaturized without the need for a separate optical system 140 and a device for alignment and uniformization of light.

The optical system 140 may be made of a material such as glass, oxide, nitride, or sapphire. The optical system 140 may include lenses. For example, the optical system 140 may include a micro lens array in which lens structures having a size of 10 to 1000 μm are arranged two-dimensionally.

The micro lens array may include micro lenses having a positive or negative curvature. In an embodiment, a width of each micro lens may be equal to or smaller than a width of each micro LED 120.

In an embodiment, each micro lens of the micro lens array may be disposed for each micro LED 120. In some embodiments, each micro lens of the micro lens array may be disposed for micro LEDs 120.

The substrate transfer unit 200 transfers the loaded target substrate 10 to an appropriate position for exposure. The substrate transfer unit 200 may include a substrate stage 210 and a substrate stage driver 220.

The substrate stage 210 supports a lower surface of the target substrate 10. The substrate stage 210 transfers the target substrate 10 in at least one of the first, second, and third directions X, Y, and Z. In an embodiment, the substrate stage 210 transfers the target substrate 10 in the first direction X such that at least a part of the target substrate 10 disposed on the substrate stage 210 overlaps the light source unit 100 in the third direction Z.

The substrate stage driver 220 moves the substrate stage 210 to transfer the target substrate 10. The substrate stage driver 220 may be electrically connected to the control unit 300 to be described later. In an embodiment, the substrate stage driver 220 may include a cylindrical roller connected to the substrate stage 210. The roller may rotate or stop so that at least a part of the target substrate 10 located on a transfer belt and requiring patterning is aligned under the light source unit 100.

The sensing unit 400 may sense whether the light source unit 100 and the target substrate 10 are aligned with each other so that the target substrate 10 can be aligned at a correct position. In an embodiment, the sensing unit 400 may be disposed under the light source unit substrate 110 to sense an alignment mark on the target substrate 10.

The control unit 300 controls at least one of the light source unit 100, the substrate transfer unit 200, and the sensing unit 400.

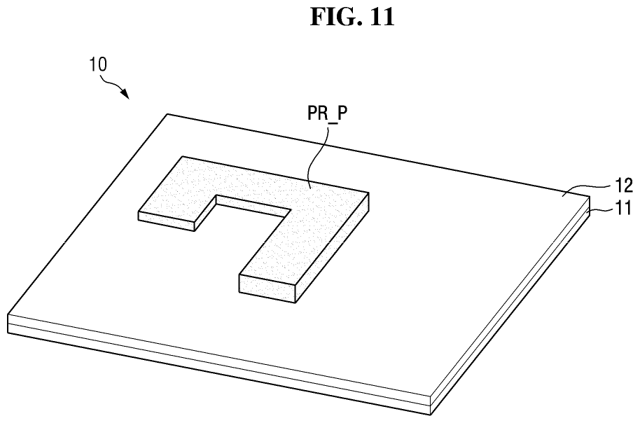

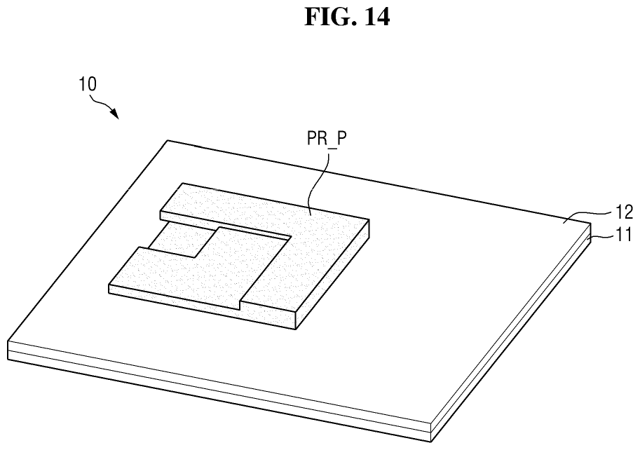

The control unit 300 may individually control each micro LED 120 of the micro LED array MLA to output a preset pattern. The preset pattern may be a pattern of light generated as the amount, intensity or brightness of light of each micro LED 120 is controlled individually. Specifically, the control unit 300 may allocate coordinates or an address to each micro LED 120 and transmit a control signal to each micro LED 120 individually based on the coordinates or the address. In an embodiment, the control unit 300 may set an X-axis address and a Y-axis address for each micro LED 120 and individually control each micro LED 120 by transmitting a control signal corresponding to the set X-axis address and Y-axis address according to the shape of the preset pattern. Accordingly, the exposure apparatus 1 can easily implement various exposure patterns according to the shape of photoresist patterns (See ‘PR_P’ in FIG. 11 and FIG. 14) to be formed on the target substrate 10 without requiring a separate mask for an exposure process.

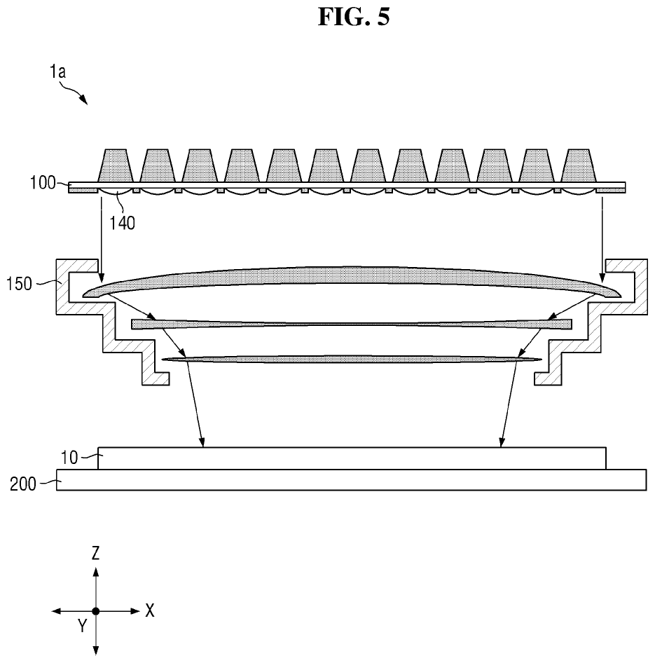

FIG. 5 illustrates an auxiliary optical system 150.

Referring to FIG. 5, an exposure apparatus 1a may further include the auxiliary optical system 150.

The auxiliary optical system 150 may be disposed between the light source unit 100 and the substrate transfer unit 200 and may include at least one lens having a positive or negative curvature. In an embodiment, the auxiliary optical system 150 may enlarge or reduce light emitted from the light source unit 100. Accordingly, the exposure apparatus 1a can form a more precise pattern of, e.g., 1 μm or less on the target substrate 10 and concentrate light on a specific area of the target substrate 10 or disperse the light according to the light intensity required for curing. In some embodiments, the auxiliary optical system 150 may align light emitted from the light source unit 100 in a certain direction.

Although one auxiliary optical system 150 is illustrated in FIG. 5, more than one auxiliary optical system 150 may also be disposed.

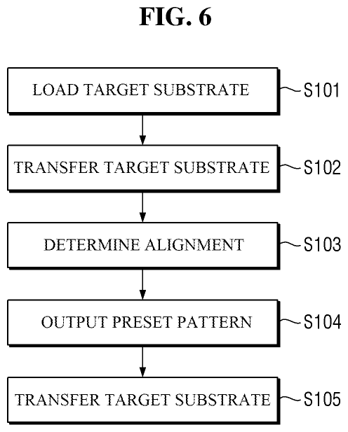

The operation of the control unit 300 will now be described in detail with reference to FIGS. 6 through 14.

FIGS. 6 through 11 illustrate a method of controlling an exposure apparatus according to an embodiment of the present disclosure.

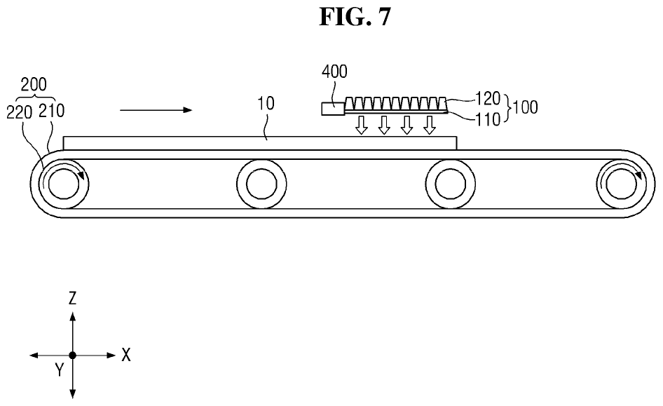

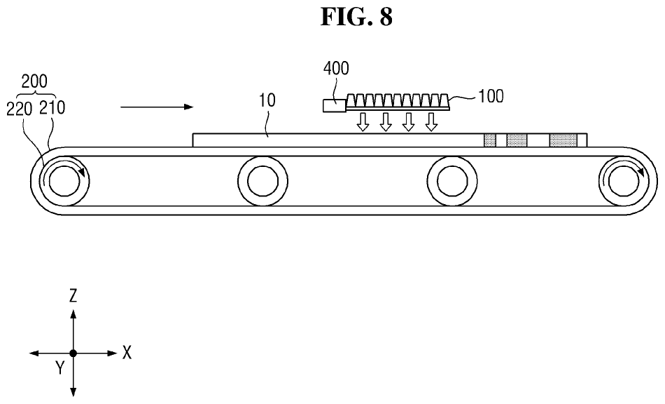

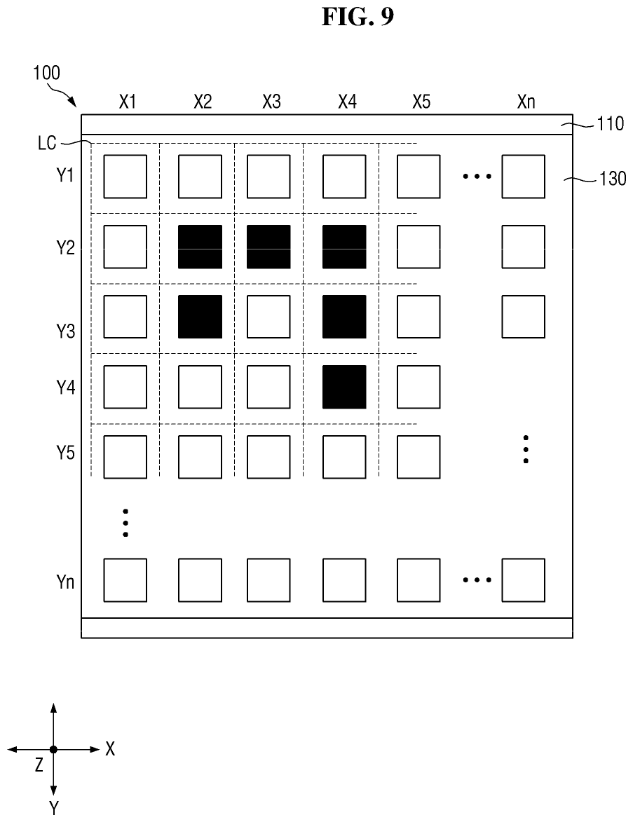

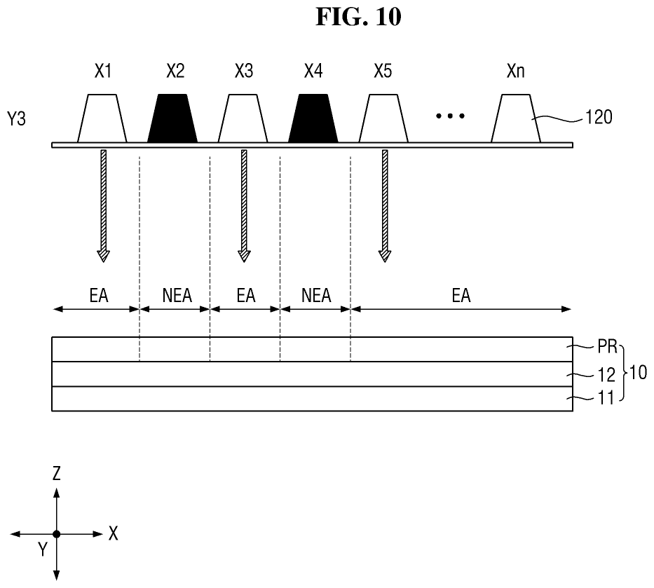

FIG. 6 is a flowchart illustrating a method of controlling an exposure apparatus according to an embodiment of the present disclosure. FIGS. 7 and 8 are side views illustrating a process in which the target substrate 10 is transferred and aligned. FIG. 9 illustrates a preset pattern. FIG. 10 illustrates an operation of outputting the preset pattern. FIG. 11 illustrates a developed photoresist pattern.

Referring to FIGS. 6 through 11, the method of controlling the exposure apparatus may include loading the target substrate 10 on the substrate transfer unit 200 in an operation S101, transferring the target substrate 10 in an operation S102, outputting a preset pattern in an operation S104, and transferring the target substrate 10 again in an operation S105. The method of controlling the exposure apparatus may be performed by the control unit 300 of the exposure apparatus 1 of FIG. 1.

The method of controlling the exposure apparatus will now be described in detail with reference to FIGS. 7 through 11.

Referring to FIG. 7, the control unit 300 controls the substrate transfer unit 200 to transfer the target substrate 10 loaded on the substrate transfer unit 200 in the first direction X.

After the transferring of the target substrate 10, the method of controlling the exposure apparatus may further include determining whether the target substrate 10 and the light source unit 100 are aligned in an operation S103.

When the target substrate 10 is located under the light source unit 100, the control unit 300 determines whether the target substrate 10 is aligned by receiving information related to the alignment from the sensing unit 400. When the target substrate 10 is not aligned, the control unit 300 controls the substrate transfer unit 200 to align the target substrate 10 at a correct position. When the target substrate 10 is aligned, the control unit 300 controls the light source unit 100 to output a preset pattern.

Referring to FIGS. 9 and 10, the preset pattern may be formed by individually turning on or off at least one unit light emitting cell LC or micro LED 120 corresponding to a specific address or coordinates. For example, the preset pattern may be a pattern in which micro LEDs 120 corresponding to (X2, Y2), (X2, Y3), (X3, Y2), (X4, Y2), (X4, Y3) and (X4, Y4) are turned off and micro LEDs 120 corresponding to the other coordinates are turned on. The preset pattern may include patterns arranged repeatedly. The preset pattern of FIG. 9 is only an example, and the preset pattern includes all of various patterns that can be used in a lithography process or an exposure and development process.

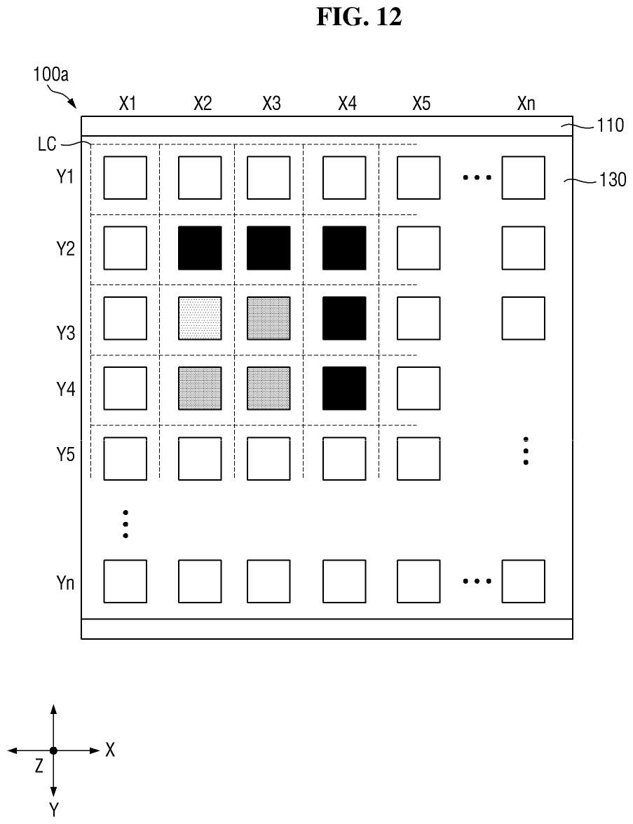

The control unit 300 may control the light source unit 100 to adjust the intensity or brightness of the preset pattern. Specifically, the control unit 300 may control the light source unit 100 such that the micro LEDs 120 emit light of the same intensity or different intensities. The intensity includes brightness. In other words, the outputting of the preset pattern may include controlling a first micro LED 120 to emit light at a first intensity and controlling a second micro LED 120 to emit light at a second intensity. Here, the first intensity and the second intensity may be the same or different. In the embodiment of FIGS. 9 and 10, the micro LEDs 120 emit light of the same intensity or brightness. However, the output of each micro LED 120 may also be controlled individually as in the embodiment of FIGS. 12 through 14.

Referring to FIG. 10, as each micro LED 120 is individually turned on or off, a part of a photosensitive material PR may be exposed, and a part of the photosensitive material PR may not be exposed. As described above, photosensitive material PR may include photoresist. Specifically, the photosensitive material PR may be divided into exposure areas EA which are exposed to light as the micro LEDs 120 disposed above the exposure area EA are turned on and non-exposure areas NEA which are not exposed to light as the micro LEDs 120 disposed above the non-exposure areas NEA are turned off, e.g., not turned on.

Referring to FIG. 10, when the photosensitive material PR includes a positive photoresist, a part of the photosensitive material PR disposed in the exposure areas EA may be removed by a developer, and a part of the photosensitive material PR disposed in the non-exposure areas NEA may remain to form a photoresist pattern PR_P as illustrated in FIG. 11. Then, a target material disposed on the base substrate 11 may be etched into a desired shape using the photoresist pattern PR_P as a mask. A photoresist pattern PR_P formed using a positive photoresist is illustrated in FIG. 11. In some embodiments, the photosensitive material PR may also include a negative photoresist.

Referring again to FIGS. 7 and 8, after the outputting of the preset pattern, the method of controlling the exposure apparatus may further include determining an exposure time.

The control unit 300 may determine whether the exposure time exceeds a preset time. The exposure time refers to a period of time during which the target substrate 10 is exposed to the preset pattern output from the light source unit 100.

When the exposure time is equal to or less than the preset time, the control unit 300 controls the light source unit 100 to continuously output the preset pattern.

When the exposure time exceeds the preset time, the control unit 300 controls the substrate transfer unit 200 to transfer the target substrate 10 in the first direction X. Here, the control unit 300 may control the light source unit 100 not to output the preset pattern any more. In some embodiments, the exposure apparatus 1 may further include an additional substrate transfer unit 200 capable of transferring the target substrate 10 in the second direction Y or the third direction Z, and the control unit 300 may control the additional substrate transfer unit 200 to transfer the target substrate 10 in a direction different from the previous transfer direction.

After the target substrate 10 is moved by a sufficient distance, the control unit 300 may again determine whether another area of the target substrate 10 is aligned with the light source unit 100.

When the area of the target substrate 10 is aligned with the light source unit 100, the control unit 300 may control the light source unit 100 to continuously output the same pattern to the area of the target substrate 10 or to output a different pattern to the area of the target substrate 10.

FIGS. 12 through 14 illustrate a method of controlling an exposure apparatus according to an embodiment of the present disclosure.

The embodiment of FIGS. 12 through 14 is different from the embodiment of FIGS. 6 through 11 in that the output of each micro LED 120 is controlled differently in an operation of outputting a preset pattern.

Referring to FIGS. 6 and 12 through 14, the control unit 300 may control the light source unit 100 such that the micro LEDs 120 emit light of different brightnesses. For example, the control unit 300 may control the light source unit 100 such that micro LEDs 120 corresponding to (X2, Y2), (X3, Y2), (X4, Y2), (X4, Y3) and (X4, Y4) are turned off, micro LEDs 120 corresponding to (X3, Y3), (X2, Y4) and (X3, Y4) emit light having a first brightness, a micro LED 120 corresponding to (X2, Y3) emits light having a second brightness, and the other micro LEDs 120 emit light having a third brightness. Accordingly, a photoresist PR disposed in each exposure area EA, e.g., EA1, EA2, EA3, may be cured to a different degree to form a stepped photoresist pattern PR_P having various heights as illustrated in FIG. 14. The photoresist PR may be divided into a non-exposure area NEA, first exposure areas EA1, a second exposure area EA2 and third exposure area EA3. The non-exposure area NEA is an area where a micro LED 120 disposed above the non-exposure area NEA is turned off. The first exposure areas EA1, the second exposure area EA2 and the third exposure area EA3 are areas where micro LEDs 120 disposed above the first exposure areas EA1, the second exposure area EA2 and the third exposure area EA3 are turned on, respectively. The light amount or emission time of micro LEDs 120 disposed above the first exposure areas EA1, the second exposure area EA2 and the third exposure area may be different. For example, the light amount or emission time of micro LEDs 120 disposed above the second exposure areas EA2 may be smaller than the light amount or emission time of a micro LED 120 disposed above the first exposure area EA1, and the light amount or emission time of micro LEDs 120 disposed above the third exposure areas EA3 may be smaller than the light amount or emission time of a micro LED 120 disposed above the second exposure area EA2. That is, the exposure apparatus 1 may individually control each micro LED 120 to obtain a photoresist pattern PR_P similar to a pattern obtained when a halftone mask is used.

The photoresist pattern PR_P of FIG. 14 is only an example.

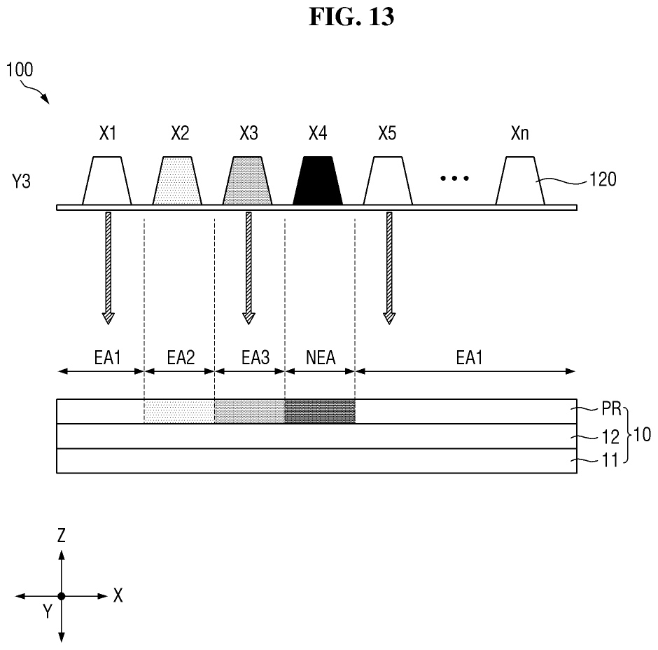

In some embodiments, the control unit 300 may control the light source unit 100 to output a first preset pattern for a first preset time and output a second preset pattern for a second preset time. Light of the micro LEDs 120 may have the same brightness as in the embodiment of FIGS. 9 and 10 or may have different brightnesses as in the embodiment of FIGS. 12 and 13. For example, the first preset pattern may be the preset pattern of FIG. 9, and the second preset pattern may be the preset pattern of FIG. 12.

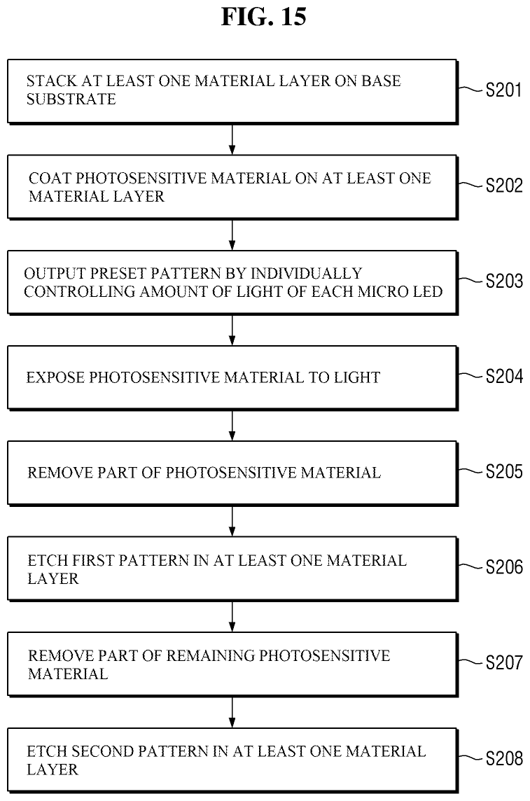

A method of manufacturing a display device using the exposure apparatus 1 will now be described in detail with reference to FIGS. 15 through 20.

FIGS. 15 through 20 illustrate a method of manufacturing a display device according to an embodiment of the present disclosure.

The exposure apparatus 1 may be used in a process requiring complicated pattern forming, for example, in a process of manufacturing a display device. Examples of the display device may include various types of display devices such as liquid crystal displays (LCDs) and organic light emitting displays (OLEDs). The method of manufacturing the display device may be performed using the exposure apparatus 1 of FIG. 1.

FIG. 15 illustrates a method of manufacturing a display device according to an embodiment of the present disclosure.

Referring to FIG. 15, the method of manufacturing the display device includes stacking at least one material layer on a base substrate 11 in an operation S201, coating a photosensitive material PR on the at least one material layer in an operation S202, outputting a preset pattern by individually controlling the amount of light of each micro LED 120 in an operation S203, exposing the photosensitive material PR to light in an operation S204, removing a part of the photosensitive material PR in an operation S205, and etching a first pattern in the at least one material layer in an operation S206. The photosensitive material PR may include a photoresist.

The individually controlling of the amount of light of each micro LED 120 may include at least one of individually controlling on or off of each micro LED 120, individually controlling a driving time of each micro LED 120, and outputting a first preset pattern for a first preset time and outputting a second preset pattern for a second preset time.

The method of manufacturing the display device may further include removing a part of the remaining photosensitive material PR in an operation S207 and etching a second pattern in the at least one material layer in an operation S208. Here, the at least one material layer may include a first layer L1 and a second layer L2 sequentially stacked from the bottom, and the first pattern may be formed in the first layer L1 and the second layer L2, and the second pattern may be formed in the second layer L2.

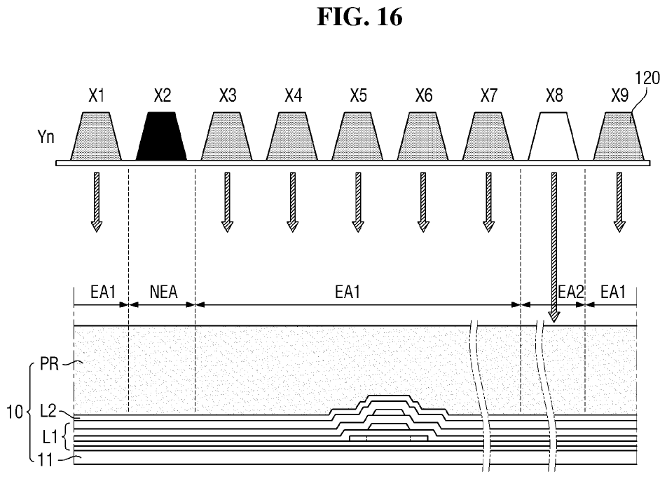

In FIGS. 16 through 20, a process of performing halftone etching using the method of manufacturing the display device of FIG. 15 is illustrated.

Referring to FIG. 16, a target substrate 10 may include a base substrate 11 and a first layer L1, a second layer L2 and the photosensitive material PR sequentially stacked on the base substrate 11.

The first layer L1 may be composed of at least one layer. For example, the first layer L1 may include a barrier layer, a buffer layer, gate insulating layers, an interlayer insulating film, and a semiconductor layer, an active layer 123, an electrode, etc. for a thin-film transistor structure.

The second layer L2 is disposed on the first layer L1. For example, the second layer L2 may be a material layer for an oxide semiconductor layer.

The photosensitive material PR is coated on the second layer L2. As the control unit 300 of the exposure apparatus 1 controls the micro LED array MLA such that each micro LED 120 emits a different amount of light or emits light for a different emission time, the photosensitive material PR may be divided into a non-exposure area NEA, first exposure areas EA1, and a second exposure area EA2. The non-exposure area NEA is an area where a micro LED 120 disposed above the non-exposure area NEA is turned off. The first exposure areas EA1 and the second exposure area EA2 are areas where micro LEDs 120 disposed above the first exposure areas EA1 and the second exposure area EA2 are turned on. The light amount or emission time of micro LEDs 120 disposed above the first exposure areas EA1 may be smaller than the light amount or emission time of a micro LED 120 disposed above the second exposure area EA2.

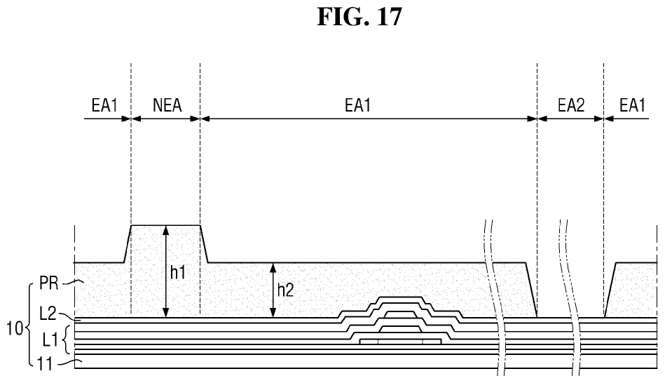

Referring to FIG. 17, a part of the exposed photosensitive material PR is removed by a development process. Specifically, when the photosensitive material PR is a positive photoresist, a part of the photosensitive material PR disposed in the non-emission area NEA may remain intact, a part of the photosensitive material PR disposed in the first exposure areas EA1 may be removed, and a part of the photosensitive material PR disposed in the second exposure area EA2 may be completely removed. In other words, a part of the photosensitive material PR disposed in the non-exposure area NEA may remain to a first height h1, and a part of the photosensitive material PR disposed in the first exposure areas EA1 may remain to a second height h2 greater than the first height h1.

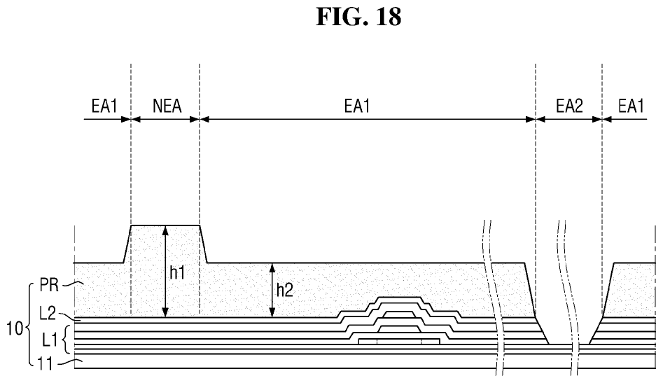

Referring to FIG. 18, parts of the first layer L1 and the second layer L2 disposed in the second exposure area EA2 may be etched using the remaining photosensitive material PR as a mask to form a first pattern. In an embodiment, the first layer L1 and the second layer L2 may be etched using different etching methods. For example, the second layer L2 may be etched using a wet etching method, and the first layer L1 may be etched using a dry etching method. Depending on the degree of etching, an opening may be formed in the first layer L1, and a groove or trench pattern may be formed in the second layer L2. The first pattern may be formed in various shapes other than the shape illustrated in FIG. 18.

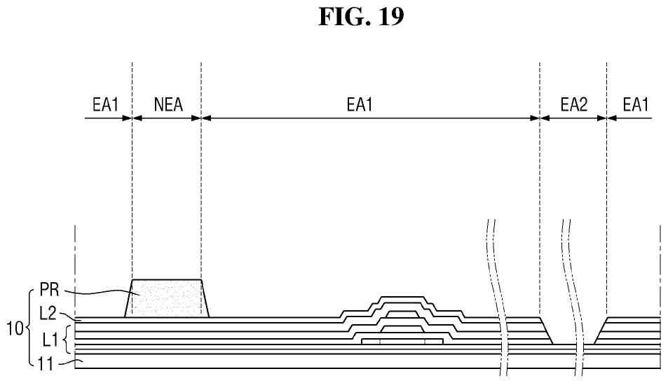

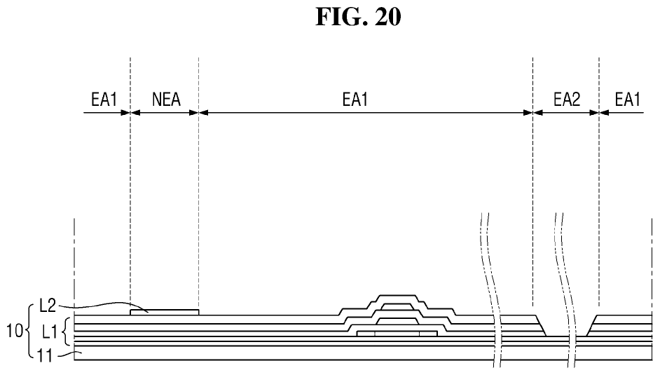

Referring to FIGS. 19 and 20, a part of the remaining photosensitive material PR is removed by an ashing process. The remaining photosensitive material PR disposed in the first exposure areas EA1 may be completely removed. Accordingly, a part of the second layer L2 disposed in the non-exposure area NEA may not be exposed, but a part of the second layer L2 disposed in the first exposure areas EA1 may be exposed. The exposed second layer L2 of the first exposure areas EA1 may be etched again to form a second pattern.

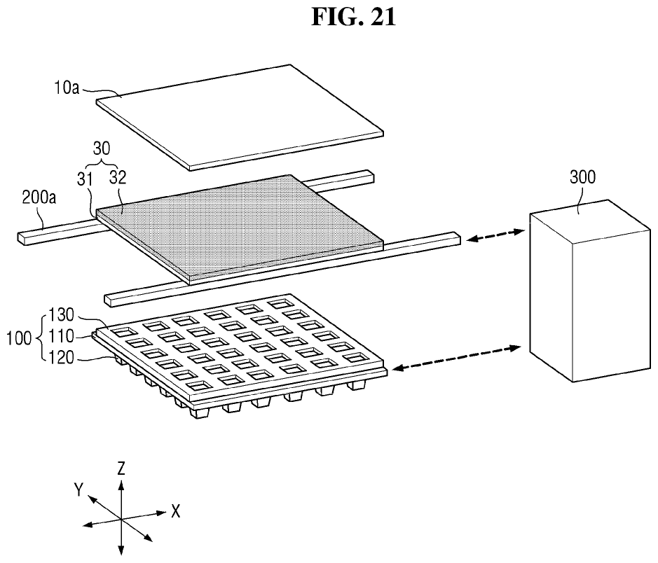

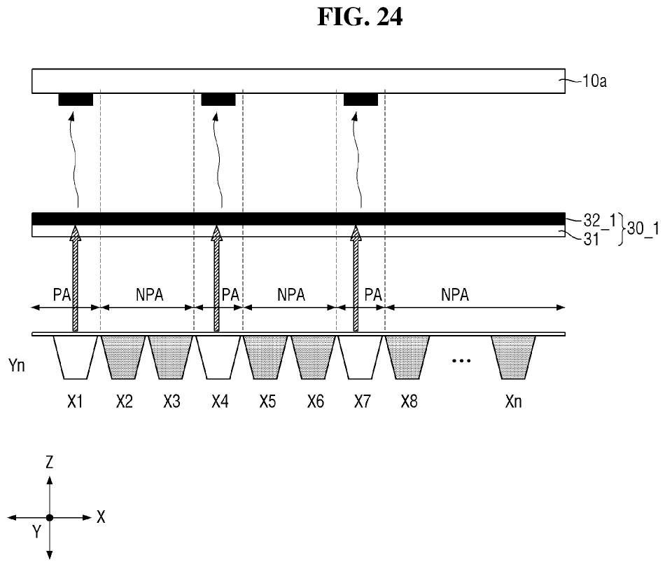

FIGS. 21 through 24 illustrate an exposure apparatus 1a and a method of manufacturing a display device using the same according to an embodiment of the present disclosure.

Referring to FIGS. 21 through 24, the exposure apparatus 1a may also be used in a deposition process, unlike the embodiments of FIGS. 1 and 20. The deposition process may be, for example, a process of depositing an organic material layer of an OLED.

A target substrate 10a may be a substrate on which a deposition source 32 evaporated by exposure is deposited. The target substrate 10a may include a base substrate and layers stacked on the base substrate to form thin-film transistors.

A donor substrate 30 refers to a substrate on which the deposition source 32 is disposed. The donor substrate 30 may include a base substrate 31 and the deposition source 32 stacked on the base substrate 31. The donor substrate 30 may include a material having high thermal conductivity, for example, a metal material.

Referring to FIG. 21, the exposure apparatus 1a may include a light source unit 100, a substrate transfer unit 200a, and a control unit 300.

The light source unit 100 is disposed under the substrate transfer unit 200a. Accordingly, during deposition, the light source unit 100, the donor substrate 30, and the target substrate 10a may be disposed to overlap each other sequentially from the bottom. The light source unit 100 may include a light source unit substrate 110, a micro LED array MLA, and a light blocking member 130. The configuration and operation of the light source unit 100 are substantially the same or similar to those of the embodiments of FIGS. 1 through 19, and thus a redundant description of the configuration and operation of the light source unit 100 will be omitted.

The substrate transfer unit 200a transfers the donor substrate 30 coated with the deposition source 32 to between the light source unit 100 and the target substrate 10a. The substrate transfer unit 200a may transfer the donor substrate 30 such that the donor substrate 30 is disposed between the light source unit 100 and the target substrate 10a during deposition. In an embodiment, the substrate transfer unit 200a may include rail parts supporting both edges of a lower surface of the donor substrate 30, so that the lower surface of the donor substrate 30 is sufficiently exposed to light emitted from the light source unit 100. The rail shape of FIG. 21 is only an example, and the substrate transfer unit 200a may be any transfer device that exposes the lower surface of the donor substrate 30 but can transfer the donor substrate 30 in at least one of the first, second, and third directions X, Y, and Z. In an embodiment, the substrate transfer unit 200a transfers the loaded donor substrate 30 in the first direction X. In some embodiments, the exposure apparatus 1a may further include at least one of a light source moving unit which moves the light source unit 100 and a target substrate transfer unit 200 which moves the target substrate 10a. The light source moving unit and the target substrate transfer unit 200 may be controlled by the control unit 300.

The control unit 300 controls the light source unit 100 and the substrate transfer unit 200a. The individual operation of each micro LED 120 by the control unit 300 is substantially the same or similar to that of the embodiments of FIGS. 1 through 20, and thus a redundant description of the individual operation of each micro LED 120 by the control unit 300 will be omitted.

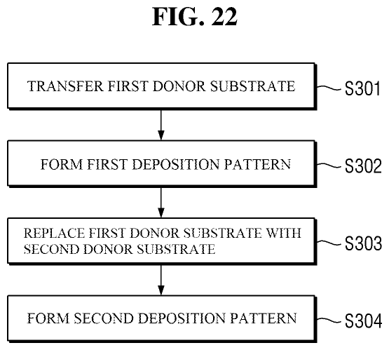

Referring to FIG. 22, the method of manufacturing the display device includes transferring a first donor substrate 30_1 in an operation S301, forming a first deposition pattern on the target substrate 10a in an operation S302, replacing the first donor substrate 30_1 with a second donor substrate 30_2 in an operation S303, and forming a second deposition pattern on the target substrate 10a in an operation S304.

The method of manufacturing the display device may further include determining whether the target substrate 10, the donor substrate 30 and/or the light source unit 100 are aligned.

The method of manufacturing the display device will now be described in detail with reference to FIGS. 21 through 24.

First, the control unit 300 controls the substrate transfer unit 200a to place the first donor substrate 30_1 at an appropriate position for deposition. The first donor substrate 30_1 may include a first deposition source 32_1.

When the first donor substrate 30_1 is transferred to a position for deposition, the control unit 300 determines whether the target substrate 10a, the first donor substrate 30_1 and/or the light source unit 100 are aligned.

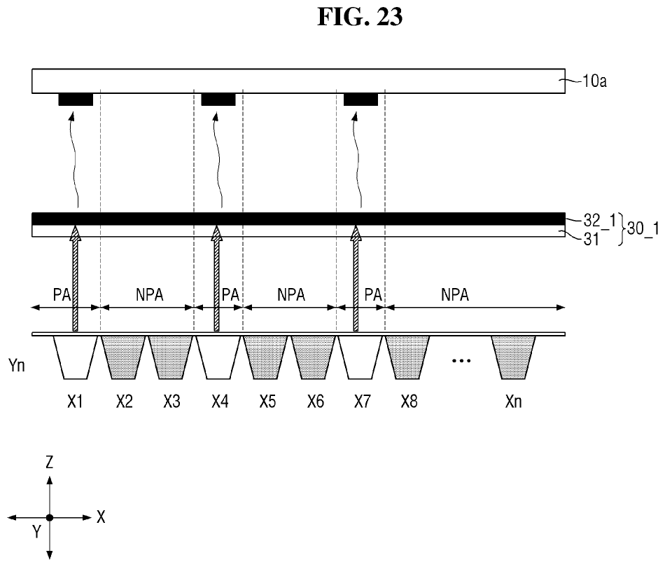

When determining that they are aligned, the control unit 300 controls the light source unit 100 to form a first deposition pattern on the target substrate 10a by exposing the first donor substrate 30_1 to light. Specifically, the control unit 300 controls the light source unit 100 to output a first preset pattern. The first preset pattern may be output for a first exposure time. The first exposure time may be a period of time sufficient to form the first deposition pattern on the target substrate 10a. The first preset pattern may be a pattern in which some of the micro LEDs 120 at predetermined intervals are turned on as illustrated in FIG. 23.

As each micro LED 120 is individually turned on or off, the deposition source 32 may be divided into deposition areas and non-deposition areas. The deposition areas may be areas where the micro LEDs 120 are turned on, and the non-deposition areas may be areas where the micro LEDs 120 are turned off. A part of the deposition source 32 disposed in the deposition areas may be evaporated and deposited on the target substrate 10a, and a part of the deposition source 32 disposed in the non-deposition areas may remain in the donor substrate 30.

When the first exposure time is equal to or greater than a first preset time, the control unit 300 may terminate the deposition process or may control a transfer stage to replace the first donor substrate 30_1 with the second donor substrate 30_2. The second donor substrate 30_2 may include a second deposition source 32_2. The second deposition source 32_2 may include the same material as or a different material from the first deposition source 32_1.

Then, the control unit 300 determines again whether the second donor substrate 30_2, the target substrate 10a and the light source unit 100 are aligned.

When determining that they are aligned, the control unit 300 controls the light source unit 100 to form a second deposition pattern on the target substrate 10a by exposing the second donor substrate 30_2 to light. Specifically, the control unit 300 controls the light source unit 100 to output a second preset pattern. The second preset pattern may be output for a second exposure time. The second preset pattern may be different from the first preset pattern. Accordingly, deposition patterns may be formed on the target substrate 10a such that different materials do not overlap each other.

In some embodiments, unlike in FIG. 23, the second preset pattern may be the same pattern as the first preset pattern, and deposition patterns may be formed on the target substrate 10a such that different materials at least partially overlap each other.

When the second exposure time is equal to or greater than a second preset time, the control unit 300 may terminate the deposition process or may replace the second donor substrate 30_2 with a third donor substrate 30.

As each micro LED 120 is driven individually, the exposure apparatus 1a does not require a mask for deposition, for example, a fine metal mask (FMM) in a deposition process.

In concluding the detailed description, those skilled in the art will appreciate that many variations and modifications can be made to the embodiments without substantially departing from the principles of the inventive concept. Therefore, the disclosed embodiments of the inventive concept are used in a generic and descriptive sense only and not for purposes of limitation.

What is claimed is:

1. An exposure apparatus comprising:
a light source unit which provides light for exposure and comprises micro light emitting diodes arranged in a matrix form;
a substrate transfer unit which transfers a target substrate; and
a control unit which controls at least one of the light source unit and the substrate transfer unit,
wherein the control unit allocates coordinates or an address to each micro light emitting diode and individually controls an amount of light of each micro light emitting diode according to a preset pattern based on the coordinates or the address.

2. The apparatus of claim 1, wherein each micro light emitting diode has a size of 100 μm or less.

3. The apparatus of claim 1, wherein an average pitch between the micro light emitting diodes is 5000 μm or less.

4. The apparatus of claim 1, wherein an emission wavelength of each micro light emitting diode is within a range of 200 to 500 nm.

5. The apparatus of claim 1, wherein the light source unit comprises:
a light source unit substrate which supports the micro light emitting diodes; and
an optical system which is disposed under the light source unit substrate.

6. The apparatus of claim 5, wherein each micro light emitting diode comprises:
a first semiconductor layer which is disposed on the light source unit substrate;
an active layer which is disposed on the first semiconductor layer;
a second semiconductor layer which is disposed on the active layer; and
a reflector which has an open lower side and surrounds the first semiconductor layer, the active layer and the second semiconductor layer.

7. The apparatus of claim 6, wherein the reflector becomes wider toward a bottom, and side surfaces of the reflector are inclined at an angle within a range of 40 to 90 degrees.

8. The apparatus of claim 5, wherein the light source unit further comprises a light blocking member which is disposed along a boundary between the micro light emitting diodes on the light source unit substrate.

9. The apparatus of claim 5, wherein the optical system comprises micro lenses.

10. The apparatus of claim 1, wherein a distance between the light source unit and the target substrate loaded on the substrate transfer unit during exposure is about 500 μm or less.

11. The apparatus of claim 1, wherein the control unit individually controls on or off of each micro light emitting diode.

12. The apparatus of claim 1, wherein the control unit individually controls a driving time of each micro light emitting diode.

13. The apparatus of claim 1, wherein the control unit controls the light source unit to output a first preset pattern for a first preset time and controls the light source unit to output a second preset pattern different from the first preset pattern when determining that the first preset time has elapsed.

14. An exposure apparatus comprising:
a light source unit which provides light for exposure and comprises unit light emitting cells arranged in a matrix form;
a substrate transfer unit which transfers a target substrate; and
a control unit which controls at least one of the light source unit and the substrate transfer unit,
wherein the control unit allocates coordinates or an address to each unit light emitting cell and individually controls an amount of light of each unit light emitting cell according to a preset pattern based on the coordinates or the address.

15. A method of manufacturing a display device, the method comprising:
stacking at least one material layer on a base substrate;
coating a photosensitive material on the at least one material layer;
outputting a preset pattern by individually controlling an amount of light of each micro light emitting diode;
exposing the photosensitive material to light;
removing a part of the photosensitive material; and
etching a first pattern in the at least one material layer.

16. The method of claim 15, wherein the individually controlling of the amount of light of each micro light emitting diode comprises individually controlling on or off of each micro light emitting diode.

17. The method of claim 15, wherein the individually controlling of the amount of light of each micro light emitting diode comprises individually controlling a driving time of each micro LED.

18. The method of claim 15, wherein the individually controlling of the amount of light of each micro light emitting diode comprises outputting a first preset pattern for a first preset time and outputting a second preset pattern for a second preset time.

19. The method of claim 15, further comprising removing a part of a remaining photosensitive material.

20. The method of claim 19, further comprising etching a second pattern in the at least one material layer.
